(19) United States
(12) Patent Application Publication
(10) Pub. No.: US 2018/0269881 A1
(43) Pub. Date: Sep. 20, 2018

(54) SIGNAL PROCESSING SYSTEM AND METHOD THEREOF

(71) Applicant: LYRA SEMICONDUCTOR INCORPORATED, Hsinchu County (TW)

(72) Inventors: HORNG-DER CHANG, Hsinchu County (TW); NAN-SHIUNG HUANG, Hsinchu County (TW); CHIA-CHI CHANG, Hsinchu County (TW)

(21) Appl. No.: 15/481,630

(22) Filed: Apr. 7, 2017

(30) Foreign Application Priority Data
Mar. 14, 2017 (TW) 106108231

(51) Int. Cl. H03L 1/04; H03B 5/08; H03L 7/197

(52) U.S. Cl. CPC H03L 1/04; H03L 7/1974; H03B 5/08

(57) ABSTRACT

The invention disclosed a signal processing system and method thereof, applicable to temperature compensation processing of resonance frequency (OSC) LC-tank oscillator. The signal processing method of the signal processing system uses a temperature sensor/ADC to obtain different K values related to different temperatures and records K values in OTPROM in temperature compensation processing module; a fractional-N frequency divider divides the higher OSC outputted by LC-tank; a linear PLL (LPLL) suppresses the timing jitter of the clock outputted by the fractional-N frequency divider, the frequency-locked loops (FLL) finds the M and N values required by fractional-N frequency divider according to the processed clock after the LPLL processing timing jitter and an applied external clock frequency, and transmits to temperature compensation processing module; and the temperature compensation processing module transmits the K, M and N values to fractional-N frequency divider so that the fractional-N frequency divider outputs accurate clock.

### CROSS-REFERENCE TO RELATED APPLICATION

The present application is based on, and claims priority form, Taiwan Patent Application No. 106108231 filed Mar. 14, 2017 the disclosure of which is hereby incorporated by reference herein in its entirety.

### TECHNICAL FIELD

The technical field generally relates to a signal processing system and method, and in particular, to a signal processing system and method, applicable to an environment of temperature compensation processing for LC-tank oscillator resonance frequency (OSC), by using temperature sensor/analog-digital-converter (ADC), temperature compensation processing module, fractional-N frequency divider, linear phase-locked loops (LPLL), and frequency-locked loops (FLL) to find the K, M and N values required by the fractional-N frequency divider for the fractional-N frequency divider to output precise clock signals.

### BACKGROUND

In the development of electronic products, due to the rapid evolution of semiconductor process technology, there have been powerful, complex large-scale integrated circuits. Some electronic products, such as mobile phones, tablet PCs, USB peripheral products, require single-chip applications; moreover, in the complex large-scale integrated circuit, but the accurately synchronized clock signals are needed to achieve high-specification processing efficiency. Therefore, the clock generator, that is, the phase-locked loop (PLL), is widely used in the frequency synthesizer, clock and data recovery circuit, and so on.

For the known non-quartz crystal oscillator, the common structures for voltage-controlled oscillator (VCO) can be divided into two types: one is the inductor capacitor tank (LC-tank) oscillator, and the other is the ring oscillator. For CMOS manufacturing process, the phase noise of the ring oscillator is still unable to meet the requirements of the VCO specification for the communication, and therefore the VCO is often designed as an LC-tank oscillator.

For high-speed input/output (I/O) interfaces and wireless communication systems, the low-cost, high-efficiency clock generators are required to use LC-tank oscillator to reduce phase noise to meet high-quality communication specification.

In an article in IEEE Journal of Solid-State Circuits, March 2007, “A monolithic and self-referenced RF LC clock generator compliant with USB 2.0”, the author, Michael S McCorquodale, disclosed how to solve the problem of frequency change from the PLL caused by XTAL due to environmental change, such as, temperature. The solution is to add a phase interpolation circuit before feeding back to the frequency divider in the PLL to shift phase to achieve adjusting the PLL output frequency at different temperatures.

Taiwan Patent No. 1558095 titled “clock generation circuit and method” disclosed a clock generation circuit and a clock generation method to generate a clock. The clock generating circuit comprises: a reference clock generating circuit disposed in a chip for independently generating a reference clock; a temperature sensor for sensing ambient temperature to generate a temperature information; a temperature compensation module coupled to the temperature sensor for generating a temperature compensation coefficient based on the temperature information; and a clock adjusting circuit coupled to the reference clock generating circuit for generating the clock, based on the reference clock and the temperature compensation coefficient; wherein the temperature compensation module dynamically generates the temperature compensation coefficient so that the frequency of the clock approaches a target frequency and does not substantially vary with temperature. However, the temperature compensation module of the “Clock Generation Circuit and Method” of Taiwan Patent No. 1558095 generates the temperature compensation coefficient corresponding to each temperature based on the reference value and the slope, and the temperature compensation coefficient is obtained by interpolation of a value N.F for a certain temperature, in order to deduce backward to obtain the temperature compensation coefficient.

Taiwan Patent No. 1485986 “Clock signal synthesis method and apparatus” disclosed a method and apparatus of adjusting the frequency of the output clock signal to the required accuracy of the oscillation frequency. An embodiment of the method comprises the steps of: entering a calibration mode; generating a first control character to control the timing of a clock signal synthesizer; adjusting the first control character until the timing of the synthesizer is substantially within a preset range of a reference clock timing; sensing a temperature by using a temperature sensor; storing the output preset value of the first control character to a nonvolatile memory; exiting the calibration mode; using the temperature sensor to sense the temperature; and generating a second control character based on the output of the nonvolatile memory and the output of the temperature sensor to control the timing of the clock signal synthesizer. However, Taiwan Patent No. 1485986 “Clock signal synthesis method and apparatus” uses a single-point calibration and temperature compensation mechanism to maintain the frequency of the clock signal to within the accuracy range of the specified frequency under the influence of process, voltage and temperature fluctuation.

Taiwan Publication No. 201543803 “Clock generation circuit and method” disclosed a clock generation circuit and a clock generation method to generate a clock. The clock generating circuit comprises: a reference clock generating circuit disposed in a chip for independently generating a reference clock; a temperature sensor for sensing ambient temperature to generate a temperature information; a temperature compensation module coupled to the temperature sensor for generating a temperature compensation coefficient based on the temperature information; and a clock adjusting circuit coupled to the reference clock generating circuit for generating the clock, based on the reference clock and the temperature compensation coefficient; wherein the temperature compensation module dynamically generates the temperature compensation coefficient so that the frequency of the clock approaches a target frequency and does not substantially vary with temperature. However, the temperature compensation module of the “Clock Generation Circuit and Method” of Taiwan Publication No. 201543803 generates the temperature compensation coefficient corresponding to each temperature based on the reference value and the slope, and the temperature compensation coefficient is obtained by interpolation of a value N.F for a certain temperature, in order to deduce backward to obtain the temperature compensation coefficient.

Therefore, the issues need to be addressed include how to adjust phase by using digital PLL to find frequency division and the relation between the temperature and the phase, instead of adjusting the phase of the VOC of the analog PLL without using XTAL, phase interpolation circuit, and single-point calibration.

### SUMMARY

An object of the present invention is to provide a signal processing system and method, applicable to an environment of the temperature compensation processing of the resonant frequency (OSC) of the LC-tank oscillator, by using temperature sensor/analog ADC to obtain the different K values associated with the different temperatures, and recording the K-values in the one-time programmable read-only-memory (OTPROM) in the temperature-compensation processing module; the fractional-N frequency divider dividing the higher frequency OSC outputted by the LC-tank oscillator; using LPLL to suppress the clock jitter in the clock outputted by the fractional-N frequency divider, the FLL finding the M-value and N-value required by the fractional-N frequency divider according to the clock processed by the LPLL for jitters, the frequency of an external clock signal applied externally, and passing the M-value and N-value to the temperature compensation processing module, and the temperature compensation processing module transmitting the K-value, M-value, and N-value to the fractional-N frequency divider so that the fractional-N frequency divider can output accurate clock signals.

Another object of the present invention is to provide a signal processing system and method, applicable to an environment of the temperature compensation processing of the resonant frequency (OSC) of the LC-tank oscillator, to use smaller chip area to achieve self-calibration of the frequency drift in the LC clock generator caused by temperature without using open loop temperature compensation circuit and binary-weighted capacitor array.

Yet another object of the present invention is to provide a signal processing system and method, applicable to an environment of the temperature compensation processing of the resonant frequency (OSC) of the LC-tank oscillator, without using XTAL, phase interpolation circuit, and single-point calibration so that the fraction-N frequency divider being able to output accurate clock signals.

Yet another object of the present invention is to provide a signal processing system and method, applicable to an environment of the temperature compensation processing of the resonant frequency (OSC) of the LC-tank oscillator, instead of adjusting the phase of the VCO in the analog PLL, but to use digital PLL to find frequency division, and the relation between the temperature and the phase to adjust the phase so that the fraction-N frequency divider being able to output accurate clock signals.

Yet another object of the present invention is to provide a signal processing system and method, applicable to an environment of the temperature compensation processing of the resonant frequency (OSC) of the LC-tank oscillator, using the physical quantity of the temperature linear changes and the linear change of the OSC frequency with the temperature change, and using two points to determine a straight line without any restriction on the temperature range, and then using fractional-N frequency division to divide the OSC frequency to the required output frequency; in other words, using two or more temperatures of non-specific values to calibrate the frequency division so that the divided frequency is a required frequency.

To achieve the aforementioned objects, the present invention provides a signal processing system, comprising: a temperature sensor/ADC, a temperature compensation processing module, a fractional-N frequency divider, a linear phase-locked loop (LPLL), and a frequency-locked loop (FLL); wherein the temperature compensation processing module comprising a temperature compensation processor, and a memory.

The temperature sensor/ADC: the temperature sensor obtains a current temperature and converts to a voltage, the ADC converts to a code character to control the K-value of the fractional-N frequency divider, with a different K-value for each different temperature.

The temperature compensation processing module: the temperature compensation processing module comprises a temperature compensation processor, and a memory, wherein the memory has a one-time programmable read only memory (OTPROM), and a lookup table; the OTPOM records two or more K values at different temperatures, for example, two K values are recorded for two point calibration, three K values are recorded for three point calibration; the temperature compensation processor uses two or more K values in the OTPROM, the lookup table, and the M value and N value from the FLL to obtain a frequency offset ratio estimation, and the frequency offset ratio estimation is sent to the fractional-N frequency divider so that the fractional-N frequency divider can output an accurate clock signal.

The fractional-N frequency divider: the fractional-N frequency divider receives higher OSC frequency outputted from the LC-tank oscillator, such as frame clock output (FCO) and generates a clock signal FOUT, and transmits the clock signal FOUTS to the LPLL.

Moreover, after the fractional-N frequency divider receives the frequency offset ratio estimation, the fractional-N frequency divider divides the higher OSC frequency outputted from the LC-tank oscillator, such as frame clock output (FCO) downwards so that the fractional-N frequency divider can output an accurate clock signal.

The LPLL: because the clock of the clock signal FOUT outputted from the fractional-N frequency divider has a larger jitter, the clock of the clock signal FOUT outputted from the fractional-N frequency divider uses the LPLL to suppress the clock jitter of the clock signal FOUT outputted from the fractional-N frequency divider.

The FLL: The LPLL transmits the clock of the clock signal FOUT after the jitter processing to the FLL, the FLL finds the M-value and the N-value required by the fractional-N frequency divider according to the clock of the clock signal FOUT after the jitter processing, the frequency of an external clock signal applied externally, such as, 24 MHz or 48 MHz, and then transmits the M-value and the N-value to the temperature compensation processing module, and the temperature compensation processor of the temperature compensation processing module uses two or more K values in the OTPROM, the lookup table, and the M-value and the N-value from the FLL to obtain a frequency shift ratio estimation and transmits the frequency shift ratio estimation to the fractional-N frequency divider so that the fractional-N frequency divider can output an accurate clock signal.

When using the signal processing system to perform signal processing method, the first step is to perform temperature measurement: the temperature sensor obtaining a current temperature and converting to a voltage, the ADC converting to a code character to control the K-value of the fractional-N frequency divider, with a different K-value for each different temperature; the OTPOM recording two or more K values at different temperatures, for example, two K values recorded for two point calibration, three K values recorded for three point calibration.

Then, the next step is to perform frequency shift ration estimation: the temperature compensation processing module using two or more K values in the OTPROM, the lookup table, and the M-value and the N-value from the FLL to obtain a frequency shift ratio estimation and transmitting the frequency shift ratio estimation to the fractional-N frequency divider.

Then, the next step is to perform accurate clock signal outputting: based on the received frequency shift ratio estimation, the fractional-N frequency divider being able to output an accurate clock signal.

Wherein, the detailed process for performing frequency shift ration estimation comprises: first, performing clock signal FOUT generation process: the fractional-N frequency divider receiving higher OSC frequency outputted from the LC-tank oscillator, such as, frame clock output (FCO) and generates a clock signal FOUT, and transmits the clock signal FOUTS to the LPLL; then, performing clock jitter processing process: because the clock of the clock signal FOUT outputted from the fractional-N frequency divider having a larger jitter, the clock of the clock signal FOUT outputted from the fractional-N frequency divider using the LPLL to suppress the clock jitter of the clock signal FOUT outputted from the fractional-N frequency divider; then, the LPLL transmitting the clock of the clock signal FOUT after the jitter processing to the FLL, the FLL finding the M-value and the N-value required by the fractional-N frequency divider according to the clock of the clock signal FOUT after the jitter processing, the frequency of an external clock signal applied externally, such as, 24 MHz or 48 MHz, and then transmitting the M-value and the N-value to the temperature compensation processing module; and, finally, performing frequency shift ratio estimation process: the temperature compensation processor of the temperature compensation processing module using two or more K values in the OTPROM, the lookup table, and the M-value and the N-value from the FLL to obtain a frequency shift ratio estimation and transmits the frequency shift ratio estimation to the fractional-N frequency divider.

The foregoing will become better understood from a careful reading of a detailed description provided herein below with appropriate reference to the accompanying drawings.

### BRIEF DESCRIPTION OF THE DRAWINGS

The embodiments can be understood in more detail by reading the subsequent detailed description in conjunction with the examples and references made to the accompanying drawings, wherein:

FIG. 1 shows a schematic view of the signal processing system collaborating with an LC-tank oscillator in accordance with an exemplary embodiment;

FIG. 2 shows a flowchart of the signal processing method used in the signal processing system in FIG. 1;

FIG. 3 shows a flowchart of detailed steps of performing the frequency shift ratio estimation process of the signal processing method in FIG. 2;

FIG. 4 shows a schematic view of an embodiment of the signal processing system and operation in collaboration with an LC-tang oscillator according to the present invention;

FIG. 5 shows a flowchart of an embodiment of the signal processing method used by the embodiment of the signal processing system of FIG. 4 and operation in collaboration with an LC-tang oscillator according to the present invention; and

FIG. 6 shows a flowchart of detailed steps of performing the frequency shift ratio estimation process of the signal processing method in FIG. 5.

### DETAILED DESCRIPTION OF THE DISCLOSED EMBODIMENTS

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

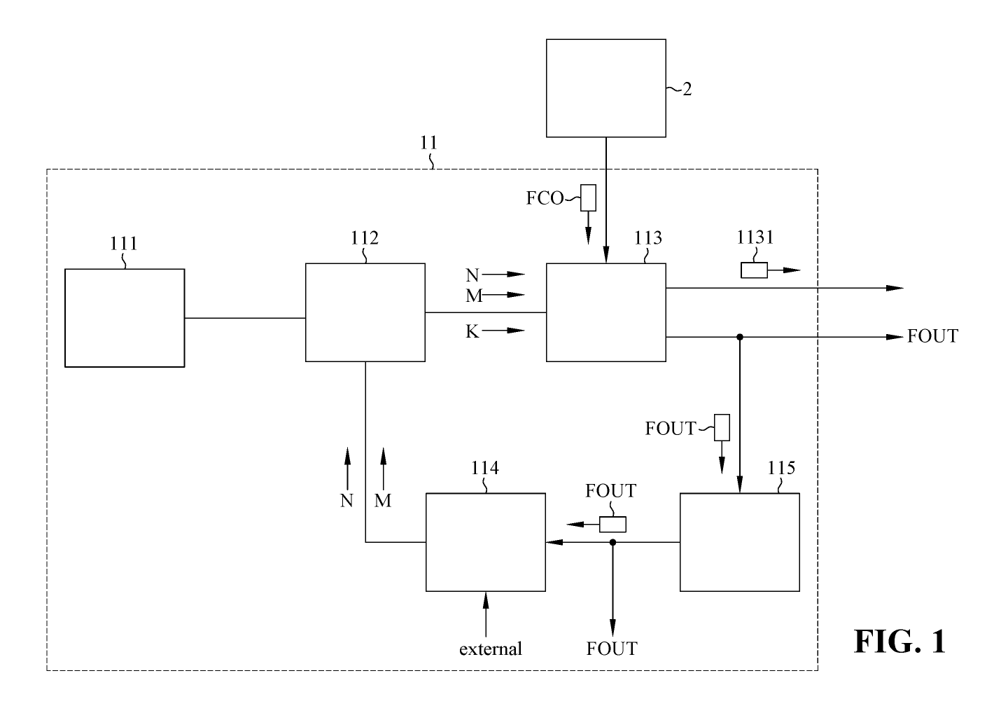

FIG. 1 shows a schematic view of the signal processing system and operation in collaboration with an LC-tank oscillator in accordance with an exemplary embodiment. As shown in FIG. 1, the signal processing system 1 comprises a temperature sensor/analog-digital-converter (ADC) 111, a temperature compensation processing module 112, a fractional-N frequency divider 113, a frequency-locked loop (FLL) 114, and a linear phase-locked loop (LPLL) 115; wherein the temperature compensation processing module 112 comprising a temperature compensation processor (not shown), and a memory (not shown).

The temperature sensor/ADC 111: the temperature sensor obtains a current temperature and converts to a voltage, the ADC converts to a code character to control the K-value of the fractional-N frequency divider 113, with a different K-value for each different temperature.

The temperature compensation processing module 112: the temperature compensation processing module 112 comprises a temperature compensation processor, and a memory, wherein the memory has a one-time programmable read only memory (OTPROM), and a lookup table; the OTPOM records two or more K values at different temperatures, for example, two K values are recorded for two point calibration, three K values are recorded for three point calibration; the temperature compensation processor uses two or more K values in the OTPROM, the lookup table, and the M value and N value from the FLL 114 to obtain a frequency offset ratio estimation, and the frequency offset ratio estimation is sent to the fractional-N frequency divider 113 so that the fractional-N frequency divider 113 can output an accurate clock signal.

The fractional-N frequency divider 113: the fractional-N frequency divider 113 receives higher OSC frequency outputted from the LC-tank oscillator 2, such as frame clock output (FCO) and generates a clock signal FOUT, and transmits the clock signal FOUTS to the LPLL 115.

Moreover, after the fractional-N frequency divider 113 receives the frequency offset ratio estimation, the fractional-N frequency divider 113 divides the higher OSC frequency outputted from the LC-tank oscillator 2, such as frame clock output (FCO) downwards so that the fractional-N frequency divider 113 can output an accurate clock signal.

The LPLL 115: because the clock of the clock signal FOUT outputted from the fractional-N frequency divider 113 has a larger jitter, the clock of the clock signal FOUT outputted from the fractional-N frequency divider 113 uses the LPLL 115 to suppress the clock jitter of the clock signal FOUT outputted from the fractional-N frequency divider 113.

The FLL 114: The LPLL 115 transmits the clock of the clock signal FOUT after the jitter processing to the FLL 114, the FLL 114 finds the M-value and the N-value required by the fractional-N frequency divider 113 according to the clock of the clock signal FOUT after the jitter processing form the LPLL 115, the frequency of an external clock signal applied externally, such as, 24 MHz or 48 MHz, and then transmits the M-value and the N-value to the temperature compensation processing module 112, and the temperature compensation processor of the temperature compensation processing module uses two or more K values in the OTPROM, the lookup table, and the M-value and the N-value from the FLL 114 to obtain a frequency shift ratio estimation (not shown) and transmits the frequency shift ratio estimation to the fractional-N frequency divider 113 so that the fractional-N frequency divider 113 can output an accurate clock signal.

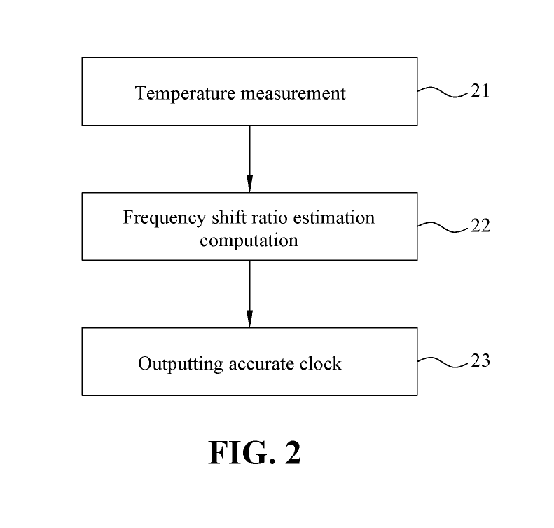

FIG. 2 shows a flowchart of the signal processing method used in the signal processing system in FIG. 1.

As shown in FIG. 2, step 21 is to perform temperature measurement: the temperature sensor/ADC 111 obtaining a current temperature and converting to a voltage, the ADC 111 converting to a code character to control the K-value of the fractional-N frequency divider 113, with a different K-value for each different temperature; the OTPOM recording two or more K values at different temperatures, for example, two K values recorded for two point calibration, three K values recorded for three point calibration. Then, proceed to step 22.

Then, step 22 is to perform frequency shift ration estimation: the temperature compensation processing module 112 using two or more K values in the OTPROM, the lookup table, and the M-value and the N-value from the FLL 114 to obtain a frequency shift ratio estimation and transmitting the frequency shift ratio estimation to the fractional-N frequency divider 113. Then. Proceed to step 23.

Step 23 is to perform accurate clock signal outputting: based on the received frequency shift ratio estimation, the fractional-N frequency divider 113 being able to output an accurate clock signal 1131.

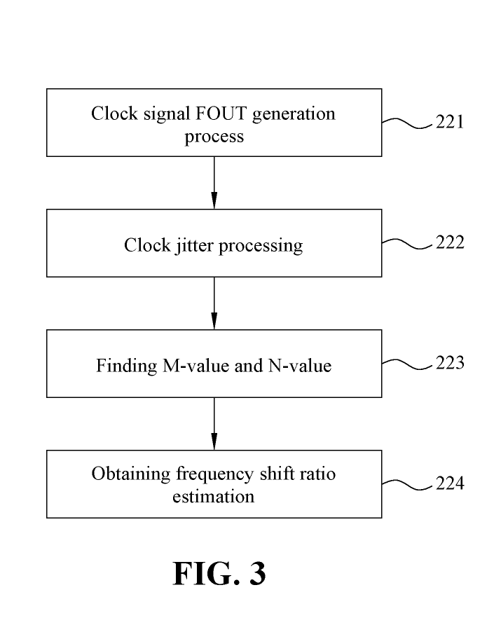

FIG. 3 shows a flowchart of detailed steps of performing the frequency shift ratio estimation process of the signal processing method in FIG. 2. As shown in FIG. 3, first, performing clock signal FOUT generation process 221: the fractional-N frequency divider 113 receiving higher OSC frequency outputted from the LC-tank oscillator 2, such as, frame clock output (FCO) and generates a clock signal FOUT, and transmitting the clock signal FOUTS to the LPLL 115 and then proceeding to process 222.

In performing clock jitter processing process 222: because the clock of the clock signal FOUT outputted from the fractional-N frequency divider 113 having a larger jitter, the clock of the clock signal FOUT outputted from the fractional-N frequency divider 113 using the LPLL 115 to suppress the clock jitter of the clock signal FOUT outputted from the fractional-N frequency divider 113; and then, proceeding to process 223.

In process 223, finding the M-value and N-value process: the LPLL 115 transmitting the clock of the clock signal FOUT after the jitter processing to the FLL 114, the FLL 114 finding the M-value and the N-value required by the fractional-N frequency divider 113 according to the clock of the clock signal FOUT after the jitter processing from LPLL 115, the frequency of an external clock signal applied externally, such as, 24 MHz or 48 MHz, and then transmitting the M-value and the N-value to the temperature compensation processing module 112; and then, proceeding to process 224.

In process 224, performing frequency shift ratio estimation process: the temperature compensation processor of the temperature compensation processing module 112 using two or more K values in the OTPROM, the lookup table, and the M-value and the N-value from the FLL 114 to obtain a frequency shift ratio estimation and transmits the frequency shift ratio estimation to the fractional-N frequency divider 113.

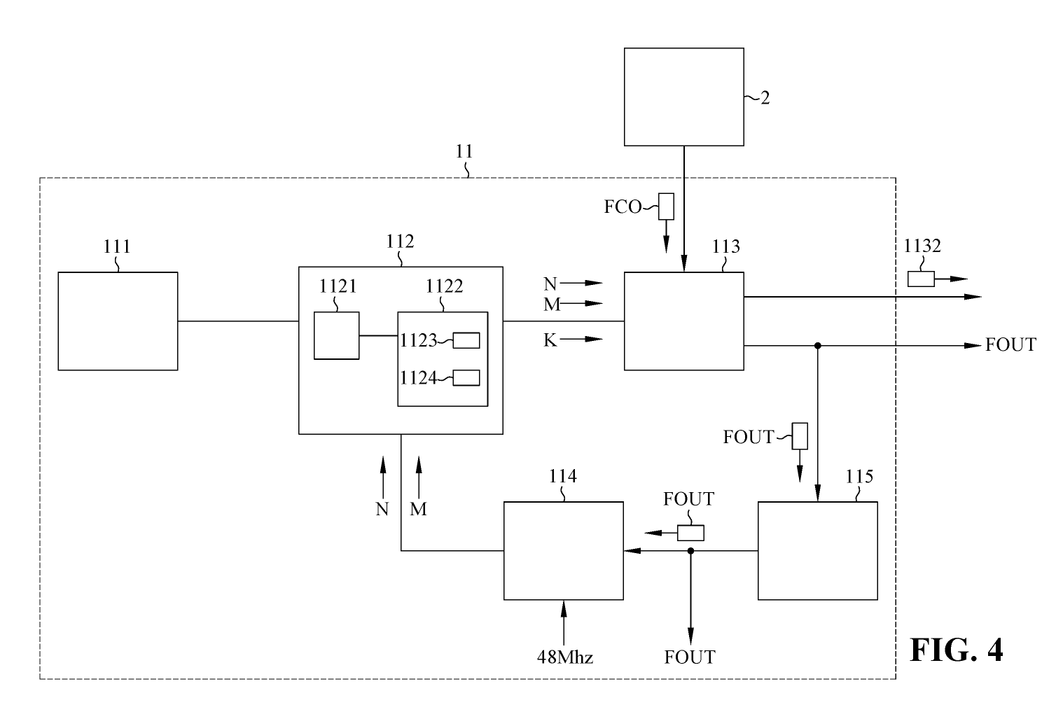

FIG. 4 shows a schematic view of an embodiment of the signal processing system and operation in collaboration with an LC-tank oscillator in accordance with an exemplary embodiment. As shown in FIG. 4, the signal processing system 11 comprises a temperature sensor/analog-digital-converter (ADC) 111, a temperature compensation processing module 112, a fractional-N frequency divider 113, a frequency-locked loop (FLL) 114, and a linear phase-locked loop (LPLL) 115; wherein the temperature compensation processing module 112 comprising a temperature compensation processor 1121, and a memory 1122. Also, when the frequency of the LC-tank oscillator 2 is a straight line, the two-point calibration will be performed; when the frequency of the LC-tank oscillator 2 is a quadratic curve, the three-point calibration will be performed; when the frequency of the LC-tank oscillator 2 is a P-order curve, the (P+1)-point calibration will be performed;

The temperature sensor/ADC 111: the temperature sensor obtains a current temperature and converts to a voltage, the ADC converts to a code character to control the K-value of the fractional-N frequency divider 113, with a different K-value for each different temperature. For example, for temperatures of 0° C./25° C./50° C., such as, at 0° C., the code character Vbe_0⇒ADC_Code_0,FLL⇒K0; while at 50° C., the code character Vbe_50⇒ADC_Code_50,FLL⇒K50; while at 25° C., the code character Vbe_25⇒ADC_Code_25,FLL⇒K25; therefore, when the temperature is at X° C., the code character Vbe_x⇒ADC_Code_X⇒Kx (the required K value); by using the lookup table to input Kx to the fractional-N frequency divider 113. Here, the exemplary temperature is not absolute. For two-point calibration, it is sufficient to measure a K-value at room temperature and a K-value at high temperature.

The temperature compensation processing module 112: the temperature compensation processing module 112 comprises a temperature compensation processor 1121, and a memory 1122, wherein the memory 1122 has a one-time programmable read only memory (OTPROM) 1123, and a lookup table (LUT) 1124; the OTPOM 1123 records two or more K values at different temperatures, for example, two K values are recorded for two point calibration, three K values are recorded for three point calibration; the temperature compensation processor 1121 uses two or more K values in the OTPROM 1123, the lookup table 1124, and the M value and N value from the FLL 114 to obtain a frequency offset ratio estimation, and the frequency offset ratio estimation is sent to the fractional-N frequency divider 113 so that the fractional-N frequency divider 113 can output an accurate clock signal 1132.

The fractional-N frequency divider 113: the fractional-N frequency divider 113 receives higher OSC frequency outputted from the LC-tank oscillator 2, such as frame clock output (FCO) and generates a clock signal FOUT, and transmits the clock signal FOUTS to the LPLL 115.

Moreover, after the fractional-N frequency divider 113 receives the frequency offset ratio estimation, the fractional-N frequency divider 113 divides the higher OSC frequency outputted from the LC-tank oscillator 2, such as frame clock output (FCO) downwards so that the fractional-N frequency divider 113 can output an accurate clock signal 1132.

The LPLL 115: because the clock of the clock signal FOUT outputted from the fractional-N frequency divider 113 has a larger jitter, the clock of the clock signal FOUT outputted from the fractional-N frequency divider 113 uses the LPLL 115 to suppress the clock jitter of the clock signal FOUT outputted from the fractional-N frequency divider 113.

The FLL 114: The LPLL 115 transmits the clock of the clock signal FOUT after the jitter processing to the FLL 114, the FLL 114 finds the M-value and the N-value required by the fractional-N frequency divider 113 according to the clock of the clock signal FOUT after the jitter processing form the LPLL 115, the frequency of an external clock signal applied externally, such as, 24 MHz or 48 MHz, and then transmits the M-value and the N-value to the temperature compensation processing module 112, and the temperature compensation processor 1121 of the temperature compensation processing module uses two or more K values in the OTPROM 1123, the lookup table 1124, and the M-value and the N-value from the FLL 114 to obtain a frequency shift ratio estimation (not shown) and transmits the frequency shift ratio estimation to the fractional-N frequency divider 113 so that the fractional-N frequency divider 113 can output an accurate clock signal 1132.

In the present embodiment, integer⇒N, f=(K+M)/2M, wherein 2M=1000000, K change by 1⇒f change by 1.0 ppm, and the LPLL 115 filters out the clock jitter outputted from the fractional-N frequency divider; the FLL 114 uses the externally applied accurate frequency 48 MHz or 24 Mhz to find N/M/K0, K25, K50, and usually 2M=1000000 is determined first, then N can be determined; M and N should be determined by the required accuracy and frequency required by the following stages.

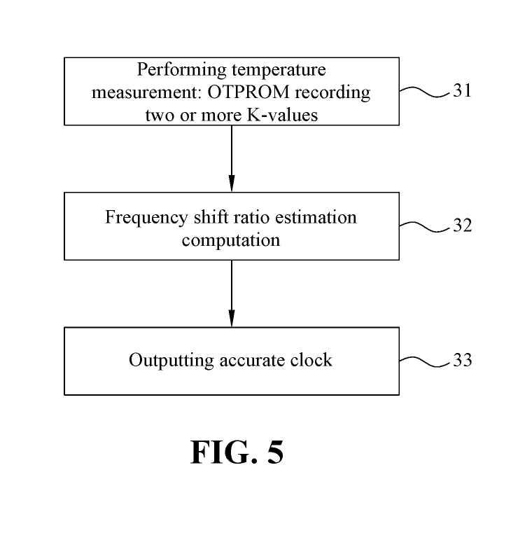

FIG. 5 shows a flowchart of the signal processing method used in the signal processing system in FIG. 4.

As shown in FIG. 5, step 31 is to perform temperature measurement: the temperature sensor/ADC 111 obtaining a current temperature and converting to a voltage, the ADC 111 converting to a code character to control the K-value of the fractional-N frequency divider 113, with a different K-value for each different temperature; the OTPOM 1123 recording two or more K values at different temperatures, for example, two K values recorded for two point calibration, three K values recorded for three point calibration. Then, proceed to step 32.

Then, step 32 is to perform frequency shift ration estimation: the temperature compensation processor 1122 using two or more K values in the OTPROM 1123, the lookup table 1124, and the M-value and the N-value from the FLL 114 to obtain a frequency shift ratio estimation and transmitting the frequency shift ratio estimation to the fractional-N frequency divider 113. Then. Proceed to step 33.

Step 33 is to perform accurate clock signal outputting: based on the received frequency shift ratio estimation, the fractional-N frequency divider 113 being able to output an accurate clock signal 1132.

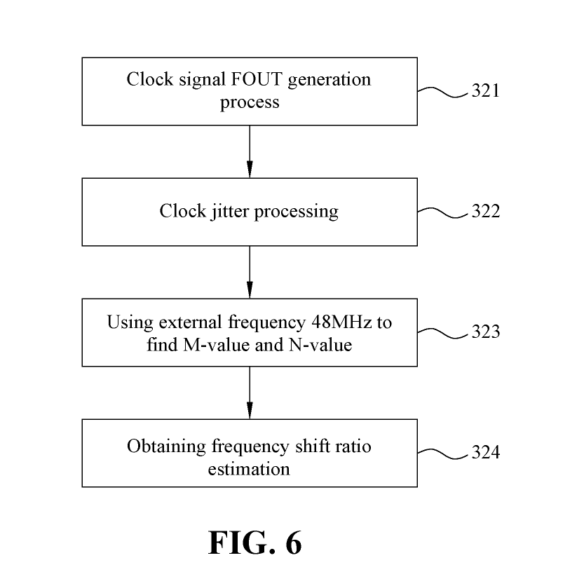

FIG. 6 shows a flowchart of detailed steps of performing the frequency shift ratio estimation process of the signal processing method in FIG. 5. As shown in FIG. 6, first, performing clock signal FOUT generation process 321: the fractional-N frequency divider 113 receiving higher OSC frequency outputted from the LC-tank oscillator 2, such as, frame clock output (FCO) and generates a clock signal FOUT, and transmitting the clock signal FOUTS to the LPLL 115 and then proceeding to process 322.

In performing clock jitter processing process 322: because the clock of the clock signal FOUT outputted from the fractional-N frequency divider 113 having a larger jitter, the clock of the clock signal FOUT outputted from the fractional-N frequency divider 113 using the LPLL 115 to suppress the clock jitter of the clock signal FOUT outputted from the fractional-N frequency divider 113; and then, proceeding to process 323.

In process 323, finding the M-value and N-value process: the LPLL 115 transmitting the clock of the clock signal FOUT after the jitter processing to the FLL 114, the FLL 114 finding the M-value and the N-value required by the fractional-N frequency divider 113 according to the clock of the clock signal FOUT after the jitter processing from LPLL 115, the frequency of an external clock signal applied externally, such as, 24 MHz or 48 MHz, and then transmitting the M-value and the N-value to the temperature compensation processing module 112; and then, proceeding to process 324.

In process 324, performing frequency shift ratio estimation process: the temperature compensation processor of the temperature compensation processor 1121 using two or more K values in the OTPROM 1123, the lookup table, and the M-value and the N-value from the FLL 114 to obtain a frequency shift ratio estimation and transmits the frequency shift ratio estimation to the fractional-N frequency divider 113.

In summary, the signal processing system and method of the present invention is applicable to an environment of the temperature compensation processing of the resonant frequency (OSC) of the LC-tank oscillator, by using temperature sensor/analog ADC to obtain the different K values associated with the different temperatures, and recording the K-values in the one-time programmable read-only-memory (OTPROM) in the temperature-compensation processing module; the fractional-N frequency divider dividing the higher frequency OSC outputted by the LC-tank oscillator; using LPLL to suppress the clock jitter in the clock outputted by the fractional-N frequency divider, the FLL finding the M-value and N-value required by the fractional-N frequency divider according to the clock processed by the LPLL for jitters, the frequency of an external clock signal applied externally, and passing the M-value and N-value to the temperature compensation processing module, and the temperature compensation processing module transmitting the K-value, M-value, and N-value to the fractional-N frequency divider so that the fractional-N frequency divider can output accurate clock signals. The signal processing system and method of the present invention provides the following advantages:

The present invention uses a temperature sensor/ADC to obtain different K values related to different temperatures and records K values in OTPROM in temperature compensation processing module; a fractional-N frequency divider divides the higher OSC outputted by LC-tank; a linear PLL (LPLL) suppresses the timing jitter of the clock outputted by the fractional-N frequency divider, the frequency-locked loops (FLL) finds the M and N values required by fractional-N frequency divider according to the processed clock after the LPLL processing timing jitter and an applied external clock frequency, and transmits to temperature compensation processing module; and the temperature compensation processing module transmits the K, M and N values to fractional-N frequency divider so that the fractional-N frequency divider outputs accurate clock.

The present invention can use smaller chip area to achieve self-calibration of the frequency drift in the LC clock generator caused by temperature without using open loop temperature compensation circuit and binary-weighted capacitor array.

The present invention, without using XTAL, phase interpolation circuit, and single-point calibration, can make the fraction-N frequency divider output accurate clock signals.

The present invention, instead of adjusting the phase of the VCO in the analog PLL, uses digital PLL to find frequency division, and the relation between the temperature and the phase to adjust the phase so that the fraction-N frequency divider being able to output accurate clock signals.

The present invention uses the physical quantity of the temperature linear changes and the linear change of the OSC frequency with the temperature change, and using two points to determine a straight line without any restriction on the temperature range, and then using fractional-N frequency division to divide the OSC frequency to the required output frequency; in other words, using two or more temperatures of non-specific values to calibrate the frequency division so that the divided frequency is a required frequency.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A signal processing method, applicable to an environment of the temperature compensation processing of a resonant frequency (OSC) of an LC-tank oscillator, comprising the following steps:
performing temperature measurement;
performing frequency shift ratio estimation computation, by using two or more temperature-related K-values, a lookup table and M-value and N-value to obtain a frequency shift ratio estimation; and
performing outputting accurate clock: based on the received frequency shift ratio estimation and outputting accurate clock signals.

2. The signal processing method as claimed in claim 1, wherein the frequency shift ratio estimation computation further comprises the following processes:
performing a clock signal FOUT generation process;
performing a clock jitter processing process, for suppressing clock jitter of the clock signal FOUT during outputting;
performing a finding M-value and N-value process, for finding required M-value and N-value according to a clock of the clock signal FOUT after jitter processing and a frequency of an external clock signal; and
performing a frequency shift ratio estimation process.

3. The signal processing method as claimed in claim 1, wherein when performing temperature measurement, a temperature sensor is used to obtain a current temperature and convert into a voltage, and an /analog-digital-converter (ADC) is used to convert the voltage into a code character to control the two or more K-values of a fractional-N frequency divider and to record the K-values.

4. The signal processing method as claimed in claim 1, wherein the step of performing frequency shift ratio estimation computation is to use two or more temperature-related K-values, the lookup table and the M-value and N-value from a frequency-locked loop (FLL) to obtain the frequency shift ratio estimation, and to transmit the frequency shift ration estimation to the fractional-N frequency divider.

5. The signal processing method as claimed in claim 1, wherein the step of performing outputting accurate clock comprises: the fractional-N frequency divider outputting the clock signal based on the received frequency shift ratio estimation.

6. The signal processing method as claimed in claim 2, wherein when performing temperature measurement, a temperature sensor is used to obtain a current temperature and convert into a voltage, and an /analog-digital-converter (ADC) is used to convert the voltage into a code character to control the two or more K-values of a fractional-N frequency divider and to record the K-values.

7. The signal processing method as claimed in claim 2, wherein the step of performing frequency shift ratio estimation computation is to use two or more temperature-related K-values, the lookup table and the M-value and N-value from a frequency-locked loop (FLL) to obtain the frequency shift ratio estimation, and to transmit the frequency shift ration estimation to the fractional-N frequency divider.

8. The signal processing method as claimed in claim 2, wherein the step of performing outputting accurate clock comprises: the fractional-N frequency divider outputting the clock signal based on the received frequency shift ratio estimation.

9. A signal processing system, applicable to an environment of the temperature compensation processing of a resonant frequency (OSC) of an LC-tank oscillator, comprising: a temperature sensor/ADC, a temperature compensation processing module, a fractional-N frequency divider, a linear phase-locked loop (LPLL), and a frequency-locked loop (FLL); wherein:
the temperature sensor/ADC: the temperature sensor obtaining a current temperature and converting to a voltage, the ADC converting to a code character of two or more K-values;
the temperature compensation processing module: the temperature compensation processing module recording the two or more K-values from the temperature sensor/ADC;
the fractional-N frequency divider: the fractional-N frequency divider receiving higher resonant frequency outputted from the LC-tank oscillator, and generating and outputting a clock signal FOUT;
the LPLL: the fractional-N frequency divider transmitting the clock signal FOUT to the LPLL, and using the LPLL to suppress clock jitter of the clock signal FOUT outputted from the fractional-N frequency divider; and
the FLL: The LPLL transmitting the clock of the clock signal FOUT after the jitter processing to the FLL, the FLL finding the M-value and the N-value required by the fractional-N frequency divider according to the clock of the clock signal FOUT after the jitter processing, the frequency of an external clock signal applied externally, and then transmitting the M-value and the N-value to the temperature compensation processing module;
wherein the temperature compensation processing module using the two or more K values, the lookup table, and the M-value and the N-value from the FLL to obtain a frequency shift ratio estimation and transmitting the frequency shift ratio estimation to the fractional-N frequency divider so that the fractional-N frequency divider able to output an accurate clock signal.

10. The signal processing system as claimed in claim 9, wherein the temperature compensation processing module comprises a temperature compensation processor, and a memory; and the memory comprises a one-time programmable read-only memory (OTPROM), and the lookup table; the OTPROM records the two or more K-values for different temperatures; the temperature compensation processor uses the the two or more K-values form the OTPROM and the M-value and N-value from the FLL to obtain the frequency shift ratio estimation.

11. The bonding structure as claimed in claim 1, wherein the buffer layer on said first adhesive metal layer and on said metal pads is separated, said first metal layer directly covers on and around said separated buffer layer and on said first adhesive metal layer located between said separated buffer layer.
